(19) United States
(12) Patent Application Publication
(10) Pub. No.: US 2026/0328805 A1
(43) Pub. Date: Oct. 22, 2026

(54) INSPECTION APPARATUS

(71) Applicant: Enplas Corporation, Kawaguchi-shi (JP)

(72) Inventor: Ryo IKEDA, Kawaguchi-shi (JP)

(73) Assignee: Enplas Corporation, Kawaguchi-shi (JP)

(21) Appl. No.: 19/463,155

(22) Filed: Jan. 29, 2026

(30) Foreign Application Priority Data
Jan. 30, 2025 (JP) 2025-014181

(51) Int. Cl. G01R 1/04; G01R 31/28

(52) U.S. Cl. CPC G01R 1/0466; G01R 31/2891

(57) ABSTRACT

Provided is an inspection apparatus that can reduce maintenance costs and ensure high measurement accuracy. The inspection apparatus measures and inspects electrical characteristics of an electronic component including a plurality of terminals, and includes: a first contact that comes into contact with a first terminal of the electronic component and through which a first current is passed during measurement; and a second contact that comes into contact with a second terminal of the electronic component and through which a second current lower than the first current is passed during measurement. The first contact includes a first coating layer on the surface of a contact with the first terminal, the second contact includes a second coating layer on the surface of a contact with the second terminal, and the first coating layer and the second coating layer are different coating layers.

### CROSS REFERENCE TO RELATED APPLICATION

This application claims the benefit of priority of Japanese Patent Application No. 2025-014181 filed on January 30, 2025, the contents of which are incorporated by reference as if fully set forth herein in their entirety.

### TECHNICAL FIELD

The present invention relates to an inspection apparatus for an electronic component such as a semiconductor module, and particularly to a technique suitable for testing a power semiconductor module.

### BACKGROUND ART

An inspection apparatus called an IC socket is used for testing an electronic component such as a semiconductor module. The IC socket includes a contact that comes into contact with a module terminal of an electronic component to be tested, and electrically connects, for example, the electronic component and a test circuit board together. In particular, an IC socket for a power semiconductor module includes a first contact through which a high current is passed and a second contact through which a low current is passed. The first contact is connected to, for example, a module terminal for power supply. The second contact is connected to, for example, a module terminal for a signal.

In the IC socket, it is required that the module terminal and the contact are in good electrical conduction when the contact is energized. In addition, it is required that a contact point of the contact that comes into contact with the module terminal has durability less susceptible to degradation due to repeated energization. Patent Literature (hereinafter, referred to as PTL) 1 discloses that a coating layer (for example, Ag plating layer) is provided on the surface of a contact to suppress diffusion of a metal component (for example, Sn) of a module terminal into the contact, thereby improving durability of the contact.

### Citation List

### Patent Literature

PTL 1

Japanese Patent Application Laid-Open No. 2018-112561

### SUMMARY OF INVENTION

### Technical Problem

Incidentally, in the IC socket, in a case where a plurality of contacts is incorporated in the same contact unit, and the contacts deteriorate and have become unusable, the contacts are replaced as a unit. In the IC socket for a power semiconductor module, the first contact for a high current and the second contact for a low current are incorporated in the same contact unit, and in a case where the first contact and the second contact have different lifespans, a still-usable healthy contact is also replaced together with the contact that has become unusable. This increases maintenance costs. In particular, in a case where the first contact and the second contact have the same structure, the lifespans thereof are often different, and there is a concern that the first contact and the second contact may not obtain good electrical conduction with the module terminal during energization with a high current or a low current, and the measurement accuracy may be reduced.

An object of the present invention is to provide an inspection apparatus that can improve durability characteristics to reduce maintenance costs while ensuring high measurement accuracy.

### Solution to Problem

An inspection apparatus according to the present invention is an inspection apparatus that measures and inspects electrical characteristics of an electronic component including a plurality of terminals, the inspection apparatus including:
a first contact that comes into contact with a first terminal of the electronic component and through which a first current is passed during measurement; and
a second contact that comes into contact with a second terminal of the electronic component and through which a second current lower than the first current is passed during measurement, in which
   the first contact includes a first coating layer on a surface of a contact with the first terminal,
   the second contact includes a second coating layer on a surface of a contact with the second terminal, and
   the first coating layer and the second coating layer are different coating layers.

### Advantageous Effects of Invention

According to the present invention, maintenance costs of the inspection apparatus can be reduced, and high measurement accuracy can be ensured as well.

### BRIEF DESCRIPTION OF DRAWINGS

FIGS. 1A and 1B are perspective views of an inspection apparatus according to an embodiment of the present invention;

FIG. 2 is a plan view showing a mounting manner of an electronic component on the inspection apparatus;

FIGS. 3A and 3B are diagrams illustrating a disposition of a contact;

FIGS. 4A and 4B are diagrams illustrating a configuration of the contact;

FIGS. 5A and 5B are cross-sectional views of a periphery of a module contact portion illustrating the configuration of the contact;

FIGS. 6A and 6B are diagrams illustrating a rib that functions as a restricting portion of the second contact;

FIG. 7 is a perspective view showing a configuration of a pressing block; and

FIG. 8 is a diagram illustrating results of durability tests of the contact.

### DESCRIPTION OF EMBODIMENTS

Hereinafter, an embodiment of the present invention will be described in detail with reference to the drawings.

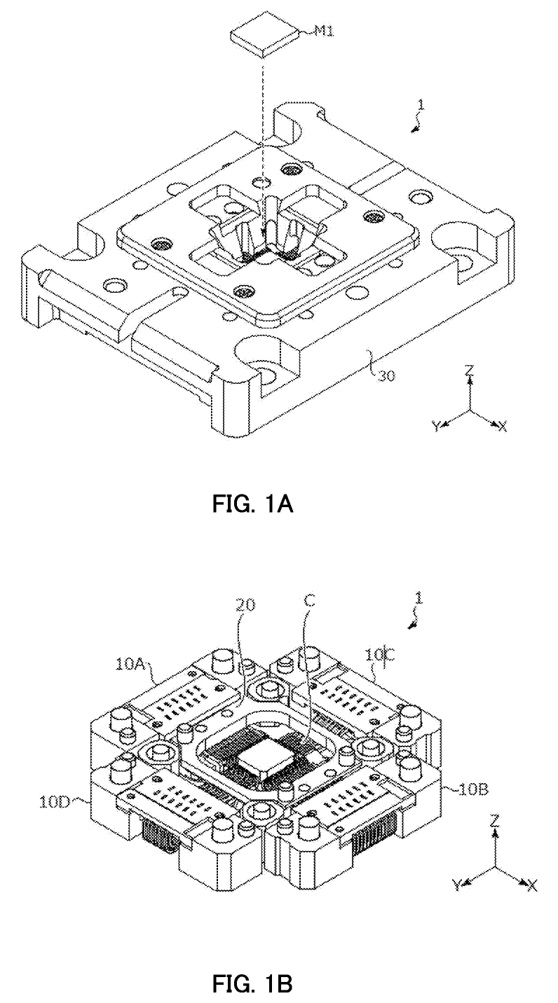

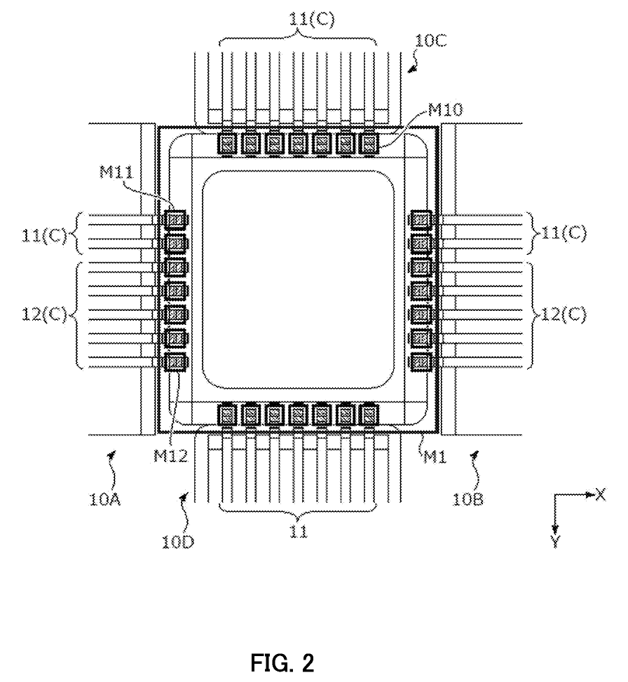

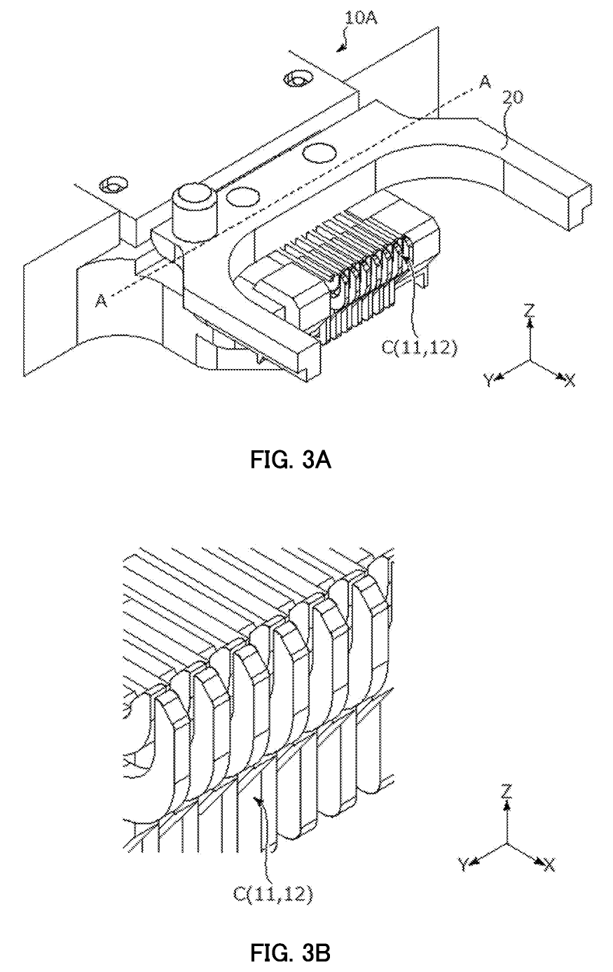

FIGS. 1A and 1B are perspective views of inspection apparatus 1 according to the embodiment of the present invention. FIG. 1A is an external perspective view of inspection apparatus 1. FIG. 1B is an external perspective view of main portions of inspection apparatus 1 without housing 30. FIG. 2 is a plan view showing a mounting manner of electronic component M1 on inspection apparatus 1. FIGS. 3A and 3B are diagrams illustrating a disposition of contact C of inspection apparatus 1. FIG. 3B is an enlarged view of a broken line portion in FIG. 3A.

In the present specification, the description will be made using an orthogonal coordinate system (X, Y, Z). The Z-axis direction is a pressing direction when mounting electronic component M1 on inspection apparatus 1. For convenience, the positive side in the Z-axis direction will be described as “upper,” and the negative side will be described as “lower.” The X-axis direction and the Y-axis direction are arrangement directions (pitch directions) of module terminal M10 of electronic component M1 and contact C of inspection apparatus 1.

Electronic component M1 is, for example, a power semiconductor module that controls or converts power, and can handle high voltage (for example, 500 V) and high current (for example, 1000 A). Electronic component M1 has a quadrilateral shape in a plan view as viewed from the Z-axis direction. Electronic component M1 includes module terminals M10 on four sides of a package. Module terminals M10 includes first module terminal M11 for power supply input and output and second module terminal M12 for signal input and output.

Here, seven module terminals M10 are disposed on each of two sides of electronic component M1 along the X-axis direction and two sides along the Y-axis direction. Among module terminals M10 disposed along the Y-axis direction, two module terminals M10 disposed on a base end side in the Y-axis direction are first module terminals M11 for power supply input and output, and five module terminals M10 disposed on a tip end side in the Y-axis direction are second module terminals M12 for signal input and output. All of module terminals M10 disposed along the X-axis direction are first module terminals M11. Note that the arrangement of module terminals M10 in electronic component M1 is merely an example, and other arrangements may be applied.

Inspection apparatus 1 is a so-called IC socket for measuring and testing electrical characteristics of electronic component M1. Inspection apparatus 1 is, for example, an IC socket for Kelvin measurement, and two contacts C are disposed to come into contact with one module terminal M10.

Inspection apparatus 1 includes contact units 10A to 10D, pressing block 20, housing 30, and the like. Contact units 10A to 10D each include contact C and contact holder 13. Contact C forms an electrical path through which a current flows during measurement. Inspection apparatus 1 may include a module holding portion (not illustrated) including a pressing mechanism, a locking mechanism, and the like that hold electronic component M1 in a stable posture.

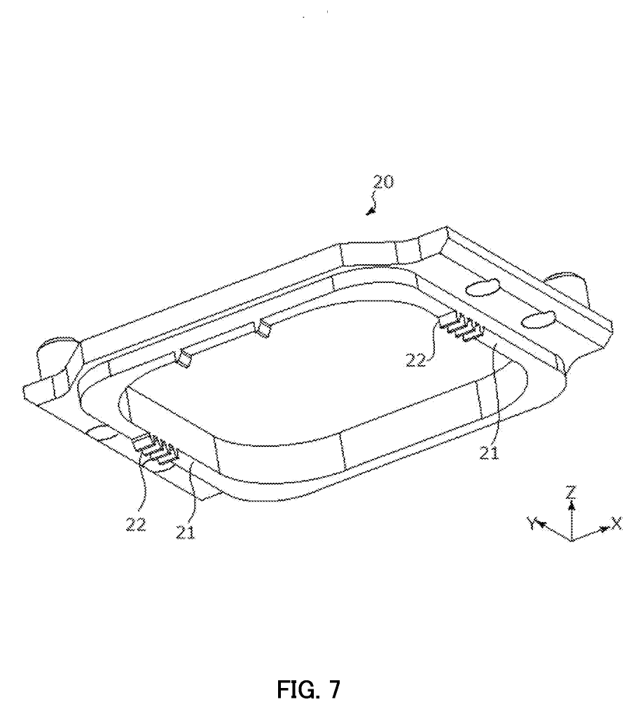

Contact units 10A to 10D are arranged such that respective contacts C form a rectangular shape corresponding to module terminals M10 of electronic component M1. That is, contact units 10A to 10D are disposed to surround a rectangular module mounting portion (reference numeral omitted) on which electronic component M1 is mounted. Pressing block 20 includes, for example, flat portion 21 (see FIG. 7) that comes into contact with contact C, and has a rectangular frame shape. Pressing block 20 is fixed to contact units 10A to 10D such that flat portion 21 presses contact C from an upper side. Housing 30 houses contact units 10A to 10D and pressing block 20.

Contact units 10A and 10B facing each other in the X-axis direction include first contact 11 and second contact 12 as contact C. Contact units 10C and 10D facing each other in the Y-axis direction include only first contact 11 as contact C. First contact 11 is a contact through which a high current is passed during measurement. Second contact 12 is a contact through which a current lower than the high current passed through first contact 11 is passed during measurement. Note that, in the present invention, a current value to be energized is not particularly limited, and any current value may be applied as long as the current passed through first contact 11 is greater than the current passed through second contact 12.

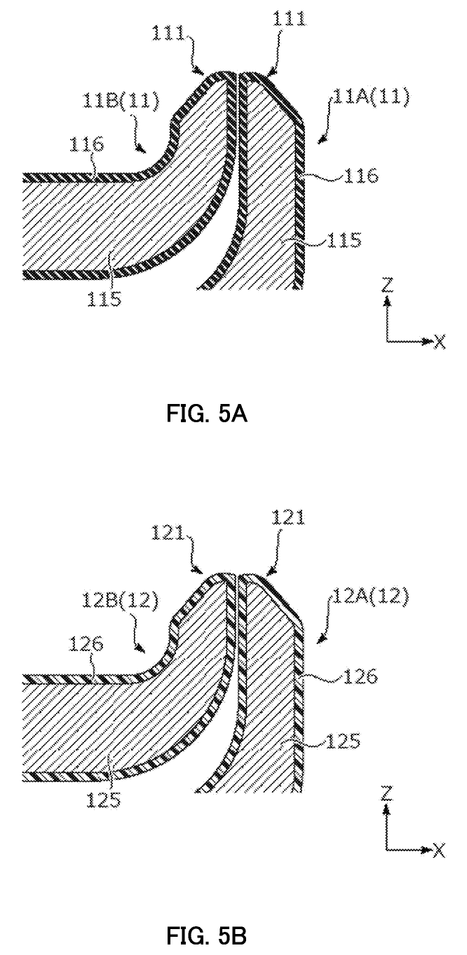

First contact 11 and second contact 12 have the same structure except for the structure of the coating layer. First contact 11 and second contact 12 are, for example, produced using the same substrates 115 and 125 (see FIGS. 5A and 5B) obtained by press-working a plate-shaped base material. In this case, the plate thicknesses of substrates 115 and 125 becomes the widths of first contact 11 and second contact 12, respectively. First contact 11 and second contact 12 are disposed such that a plate thickness direction thereof matches the pitch direction. Substrates 115 and 125 may be produced by cutting out the base material by wire cutting.

First contact 11 and second contact 12 are fixed to contact holder 13 while being insulated from each other. When first contact 11 or second contact 12 deteriorates and has become unusable, contact units 10A to 10D are replaced on a unit-by-unit basis.

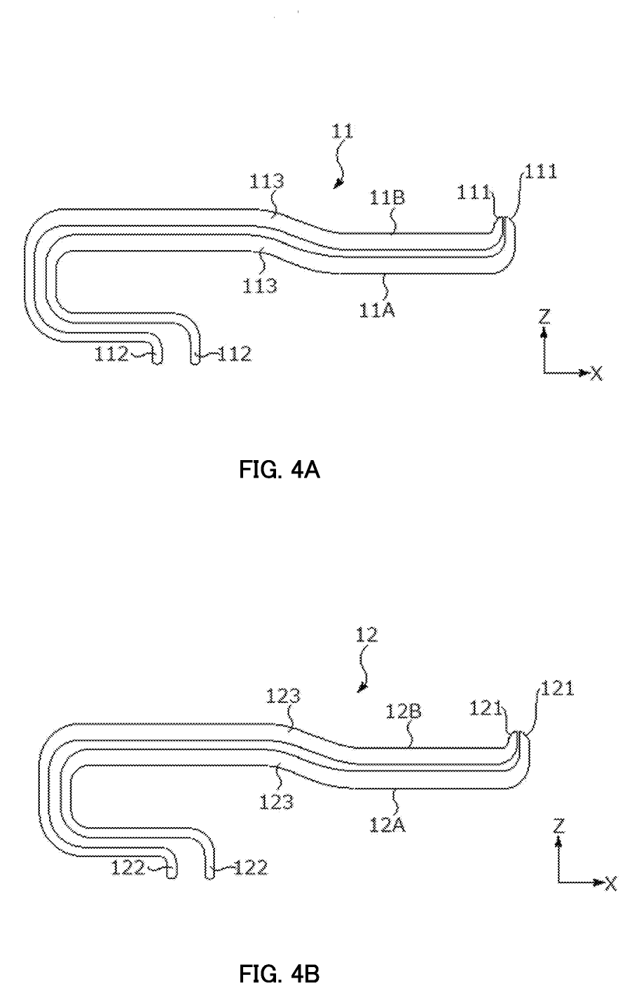

First contact 11 includes module contact portion 111, surface mounting portion 112, and spring portion 113 (see FIG. 4A). Module contact portion 111 is a portion that comes into contact with first module terminal M11. Surface mounting portion 112 is a portion that comes into contact with a terminal (not illustrated) of a test circuit board. Spring portion 113 is a portion that connects module contact portion 111 and surface mounting portion 112. The shape of first contact 11 illustrated in FIG. 4A is merely an example, and other shapes can also be applied.

Spring portion 113 includes a portion that extends in a direction (X-axis direction in FIG. 4A) orthogonal to the pitch direction and a pressing direction when mounting electronic component M1 (Z-axis direction). As illustrated in FIG. 4A, the extending portion may have a locally inclined portion or may have a linear shape. Spring portion 113 is elastically deformed in the pressing direction and exerts a biasing force when electronic component M1 is mounted. Module contact portion 111 and surface mounting portion 112 are each formed to be bent from the end portion of spring portion 113 in the Z-axis direction. First contact 11 is assembled to contact holder 13 such that elastic deformation of spring portion 113 is allowed. Module contact portion 111 and surface mounting portion 112 do not exhibit a biasing force when electronic component M1 is mounted or the biasing force can be ignored as compared with the biasing force of spring portion 113, and thus module contact portion 111 and surface mounting portion 112 can be functionally referred to as “non-spring portions.”

First contact 11 is disposed to correspond to first module terminal M11 of electronic component M1. In the present embodiment, a pair of first contacts 11A and 11B are disposed to come into contact with one first module terminal M11. One of the pair of first contacts 11A and 11B (for example, first contact 11A) is a force contact for detecting current, and the other (for example, first contact 11B) is a sense contact for detecting voltage.

First contact 11A of which module contact portion 111 is located on an inner side (side close to electronic component M1) is referred to as “inner first contact 11A,” and first contact 11B of which module contact portion 111 is located on an outer side (side far from electronic component M1) is referred to as “outer first contact 11B.” Spring portion 113 of inner first contact 11A is located below outer first contact 11B. An insulating plate (not illustrated) is interposed between spring portion 113 of inner first contact 11A and spring portion 113 of outer first contact 11B.

Second contact 12 includes module contact portion 121, surface mounting portion 122, and spring portion 123 (see FIG. 4B), similarly to first contact 11. Module contact portion 121 is a portion that comes into contact with second module terminal M12. Surface mounting portion 122 is a portion that comes into contact with a terminal (not illustrated) of a test circuit board. Spring portion 123 is a portion that connects module contact portion 121 and surface mounting portion 122. Note that the shape of second contact 12 illustrated in FIG. 4B is merely an example, and other shapes can also be applied.

Spring portion 123 includes a portion that extends in a direction (X-axis direction in FIG. 4B) orthogonal to the pitch direction and the pressing direction when mounting electronic component M1 (Z-axis direction). As illustrated in FIG. 4B, the extending portion may have a locally inclined portion or may have a linear shape. Spring portion 123 is elastically deformed in the pressing direction and exerts a biasing force when electronic component M1 is mounted. Module contact portion 121 and surface mounting portion 122 are each formed to be bent from the end portion of spring portion 123 in the Z-axis direction. Second contact 12 is assembled to contact holder 13 such that elastic deformation of spring portion 123 is allowed. Module contact portion 121 and surface mounting portion 122 do not exhibit a biasing force when electronic component M1 is mounted or the biasing force can be ignored as compared with the biasing force of spring portion 123, and thus module contact portion 121 and surface mounting portion 122 can be functionally referred to as “non-spring portions.”

Second contact 12 is disposed to correspond to second module terminal M12 of electronic component M1. In the present embodiment, a pair of second contacts 12A and 12B are disposed to come into contact with one second module terminal M12. One of the pair of second contacts 12A and 12B (for example, second contact 12A) is a force contact for detecting current, and the other (for example, second contact 12B) is a sense contact for detecting voltage.

Second contact 12A of which module contact portion 121 is located on an inner side (side close to electronic component M1) is referred to as “inner second contact 12A,” and second contact 12B of which module contact portion 121 is located on an outer side (side far from electronic component M1) is referred to as “outer second contact 12B.” Spring portion 123 of inner second contact 12A is located below outer second contact 12B. An insulating plate (not illustrated) is interposed between spring portion 123 of inner second contact 12A and spring portion 123 of outer second contact 12B.

During measurement, currents having different magnitudes are passed through first contact 11 and second contact 12. In the present embodiment, first contact 11 and second contact 12 each have a configuration suitable for the current to be passed. The configuration suitable for the current to be passed is a configuration in which durability can be improved and good conduction with module terminal M10 can be achieved.

FIG. 5A is a cross-sectional view of a periphery of module contact portion 111 showing the configuration of first contact 11. FIG. 5B is a cross-sectional view of a periphery of module contact portion 121 showing the configuration of second contact 12.

As illustrated in FIG. 5A, first contact 11 includes substrate 115 and first coating layer 116. Substrate 115 is formed of a conductive material. As a material of substrate 115, for example, a beryllium copper alloy can be applied. First coating layer 116 is formed to cover substrate 115. First coating layer 116 may be formed to cover the entire surface of substrate 115 or may be formed to cover only the periphery of module contact portion 111.

First coating layer 116 has characteristics suitable for measurement with a high current (for example, 100 A). Specifically, first coating layer 116 has a lower electrical resistivity than second coating layer 126. First coating layer 116 is composed of, for example, a metal plating layer. The metal plating layer is preferably a plating layer containing Ag (Ag plating layer or Ag alloy plating layer). The electrical resistivity of first coating layer 116 is, for example, 0.015 × 10⁻⁴ Ω·cm.

The coating layer of first contact 11 may have a monolayer structure or a multilayer structure. That is, in the present embodiment, first coating layer 116 is directly formed on substrate 115, but one, two, or more intermediate coating layers may be interposed between substrate 115 and first coating layer 116. As the intermediate coating layer, a known coating such as a Pd-Ag layer, a Pd-Sn layer, a Pd-Au layer, a Pd-Ag-Cu layer, or a Pd-Ag-Sn layer can be applied.

By providing first coating layer 116 as a surface layer of first contact 11, it is possible to suppress heat generation in module contact portion 111 during energization with a high current. As a result, deterioration of first contact 11 due to heat generation is suppressed to improve durability, and the contact state between module terminal M10 and first contact 11 is stabilized, thereby obtaining good conductivity.

In particular, in a case where first coating layer 116 is formed of a plating layer containing Ag, alloying due to diffusion of the metal component of module terminal M10 is suppressed, so that module terminal M10 and first contact 11 can be prevented from being firmly bonded to each other, and electronic component M1 can be easily replaced without damaging contact 11.

Note that, in a case where first coating layer 116 is applied as the surface layer of second contact 12 for a low current, the oxide (for example, SnO₂) of the metal component of module terminal M10 is likely to be deposited on module contact portion 121 as compared with the case where second coating layer 126 is applied. As a result, the contact state between module terminal M10 and second contact 12 becomes unstable, and second contact 12 may deteriorate due to discharge, which possibly reduces durability. Therefore, first coating layer 116 is not preferred as the surface layer of second contact 12 for a low current.

As illustrated in FIG. 5B, second contact 12 includes substrate 125 and second coating layer 126. Substrate 125 is formed of a conductive material. As a material of substrate 115, for example, a beryllium copper alloy can be applied. The same material as substrate 115 of first contact 11 can be applied to substrate 125. Second coating layer 126 is formed to cover substrate 125. Second coating layer 126 may be formed to cover the entire surface of substrate 125 or may be formed to cover only the periphery of module contact portion 121.

Second coating layer 126 has characteristics suitable for measurement with a low current (for example, 1 A or less). Specifically, second coating layer 126 has a characteristic that a metal oxide is relatively difficult to adhere. Second coating layer 126 is composed of, for example, a conductive carbon coating layer. The conductive carbon coating layer may be a DLC coating layer or a graphite coating layer. The electrical resistivity of second coating layer 126 is, for example, less than 1 × 10⁻² Ω·cm. The conductive carbon coating layer is formed, for example, by using a chemical vapor deposition (CVD) method or a physical vapor deposition (PVD) method after performing chemical polishing treatment on a surface of substrate 125. In addition, the electrical resistivity of second coating layer 126 is preferably 1 × 10⁻³ Ω·cm or less.

The coating layer of second contact 12 may have a monolayer structure or a multilayer structure. That is, in the present embodiment, second coating layer 126 is directly formed on substrate 125, but one, two, or more intermediate coating layers may be interposed between substrate 125 and second coating layer 126. It is preferred to use a coating layer having a hardness of 400 Hv or more as the intermediate coating layer on which the second coating layer is laminated. A known coating may be applied as the intermediate coating layer.

By providing second coating layer 126 as the surface layer of second contact 12, it is possible to prevent the oxide (for example, SnO₂) of the metal component of module terminal M10 from adhering to module contact portion 121 during energization with a low current, and to maintain a clean surface state. As a result, the contact state between module terminal M10 and second contact 12 is stabilized to obtain good conductivity, and deterioration of second contact 12 due to discharge can be suppressed, thereby improving durability.

Note that, in a case where above-described second coating layer 126 is applied as the surface layer of first contact 11 for a high current, heat generation during energization with a high current is increased as compared with the case where first coating layer 116 is applied, second coating layer 126 deteriorates, and as a result, the effect of suppressing adhesion of the metal oxide (for example, SnO₂) is impaired. Consequently, first contact 11 may deteriorate due to discharge, which possibly reduces durability. Therefore, second coating layer 126 is not preferred as the surface layer of first contact 11 for a high current.

In the test of electronic component M1, electronic component M1 is mounted on inspection apparatus 1, and module terminal M10 of electronic component M1 and contact C are elastically in contact with each other while a predetermined contact load is applied.

As described above, chemical polishing treatment is performed on substrate 125 of second contact 12 as pretreatment of the step of forming second coating layer 126. Thus, in a case where substrate 115 of first contact 11 and substrate of 125 of second contact 12 have the same structure, the plate thickness of second contact 12 is thinner than the plate thickness of first contact 11, and spring portion 123 is likely to be deformed in the pitch direction (plate thickness direction) when electronic component M1 is mounted. That is, second contact 12 has a structure that is likely to be shifted in the pitch direction as compared with first contact 11, and thus the contact accuracy with module terminal M10 possibly decreases.

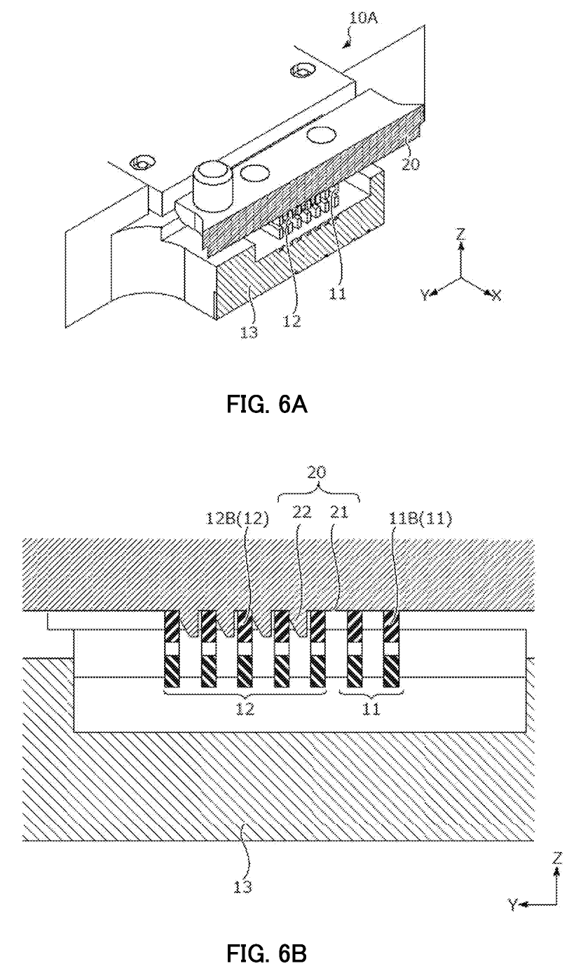

In the present embodiment, the position of second contact 12 in the pitch direction is restricted by providing a restricting portion. As illustrated in FIGS. 6A and 6B, the restricting portion is composed of, for example, rib 22 that is formed to protrude from flat portion 21 of pressing block 20. FIG. 6A is a cross-sectional perspective view taken along line A-A in FIG. 3A. FIG. 6B is a cross-sectional view as viewed from a tip end side in the X-axis direction.

As illustrated in FIG. 6B, rib 22 is disposed on one or both sides of spring portion 123 of outer second contact 12B, for example. Rib 22 is disposed to form a gap with spring portion 123, for example. By providing the gap, the elastic deformation of spring portion 123 of outer second contact 12B in the pressing direction is not constrained by rib 22, so that module terminal M10 and module contact portion 121 can be brought into contact with each other with an appropriate contact load when electronic component M1 is mounted.

In addition, pressing block 20 can define the height positions of module contact portion 111 of outer first contact 11B and module contact portion 121 of outer second contact 12B by flat portion 21. The height position of flat portion 21 that comes into contact with outer first contact 11B and the height position of flat portion 21 that comes into contact with outer second contact 12B in the pressing direction may be the same or different from each other. By providing a step between flat portion 21 coming into contact with outer first contact 11B and flat portion 21 coming into contact with outer second contact 12B to make the height positions in the pressing direction different from each other, appropriate contact loads suitable for each can be easily obtained.

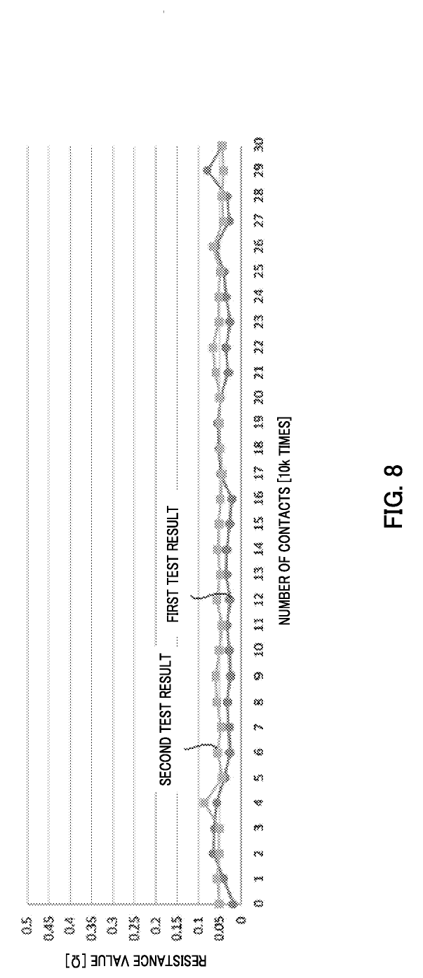

FIG. 8 is a diagram illustrating the results of durability tests of first contact 11 and second contact 12. For first contact 11, a first test was repeatedly performed in which a current terminal was brought into contact to apply a high current (5 A) for 5 msec. For second contact 12, a second test was repeatedly performed in which a current terminal was brought into contact to apply a low current (only a measurement current (1 A or less) without an applied current). Both of the first test and the second test simulate the measurement of the electrical characteristics of electronic component M1 using inspection apparatus 1.

As illustrated in FIG. 8, the resistance values of both first contact 11 and second contact 12 are stable even after 300,000 test cycles or more, and the durability is maintained. On the other hand, although not shown, in a case where the first test is repeatedly performed on second contact 12 and the second test is repeatedly performed on first contact 11, the resistance values increased by 10 times or more after approximately 1000 test cycles. From these results, the usefulness of applying first coating layer 116 as the surface layer of first contact 11 for a high current and applying second coating layer 126 as the surface layer of second contact 12 for a low current was confirmed.

As described above, inspection apparatus 1 according to the embodiment has the following features alone or in combination as appropriate.

That is, inspection apparatus 1 is an inspection apparatus that measures and tests electrical characteristics of electronic component M1 including a plurality of module terminals M10. Inspection apparatus 1 includes: first contact 11 that comes into contact with first module terminal M11 (first terminal) of electronic component M1 and through which a high current (first current) is passed during measurement; and second contact 12 that comes into contact with second module terminal M12 (second terminal) of electronic component M1 and through which a low current (second current lower than the first current) is passed during measurement. First contact 11 includes first coating layer 116 on the surface of module contact portion 111 (contact with the first terminal), second contact 12 includes second coating layer 126 on the surface of module contact portion 121 (contact with the second terminal), and first coating layer 116 and second coating layer 126 are different coating layers.

Specifically, first coating layer 116 has a lower electrical resistivity than second coating layer 126. In addition, second coating layer 126 is less prone to metal oxide adhesion than first coating layer 116.

According to inspection apparatus 1, coating layers 116 and 126 suitable for energization are formed on the surfaces of first contact 11 for a high current and second contact 12 for a low current, respectively, thereby improving the durability of first contact 11 and second contact 12. The lifespans of first contact 11 and second contact 12 are easily matched, and thus it is possible to suppress replacing of a contact unit including a healthy contact and to reduce the maintenance costs. In addition, first contact 11 and second contact 12 can obtain good conductivity with module terminal M10, thereby ensuring high measurement accuracy.

More specifically, in inspection apparatus 1, first coating layer 116 is a plating layer containing Ag, and second coating layer 126 is a conductive carbon coating layer. This makes it possible to improve the durability of each of first contact 11 and second contact 12 and to obtain good conductivity with module terminal M10.

In inspection apparatus 1, first contact 11 and second contact 12 are produced using the same substrates 115 and 125 obtained by processing a plate material, and are disposed such that the plate thickness direction matches the pitch direction. This can reduce the manufacturing cost of contact C and accommodate narrower pitch.

Inspection apparatus 1 further includes a restricting portion that restricts the position of second contact 12 in the pitch direction. Second contact 12 has a thinner plate thickness than first contact 11 due to chemical polishing when forming second coating layer 126, and thus is likely to be deformed in the pitch direction. By providing the restricting portion, misalignment between module contact portion 121 of second contact 12 and second module terminal M12 can be prevented, and the contact accuracy of module contact portion 121 and second module terminal M12 can be improved.

In inspection apparatus 1, first contact 11 and second contact 12 include spring portions 113 and 123 that are elastically deformable in the pressing direction when mounting electronic component M1, and the restricting portion is disposed on one or both sides of spring portion 123 of second contact 12 in the pitch direction. This makes it possible to restrict the elastic deformation of spring portion 123 of second contact 12 in the pitch direction, and to prevent the misalignment of module contact portion 121.

Inspection apparatus 1 further includes pressing block 20 that presses first contact 11 and second contact 12 in the pressing direction. Pressing block 20 includes: flat portion 21 that comes into contact with first contact 11 and second contact 12; and rib 22 that is formed to protrude from flat portion 21 and functions as the restricting portion. Thus, the misalignment of module contact portion 121 of second contact 12 can be prevented by using pressing block 20 that defines the height positions of first contact 11 and the second contact.

In inspection apparatus 1, pressing block 20 includes flat portion 21 that comes into contact with outer first contact 11B (first contact) and flat portion 21 that comes into contact with outer second contact 12B (second contact) at different height positions. By providing a step between flat portion 21 that comes into contact with outer first contact 11B and flat portion 21 that comes into contact with outer second contact 12B to make the height positions in the pressing direction different from each other, contact loads appropriate for outer first contact 11B and outer second contact 12B can be easily obtained.

Although the invention made by the present inventor has been specifically described based on the embodiment, the present invention is not limited to the embodiment, and can be modified without departing from the spirit thereof.

In the embodiment, the present invention has been described in the case where the present invention is applied to the inspection apparatus for Kelvin measurement, but the present invention can be applied to an inspection apparatus measuring by a method other than Kelvin measurement. In addition, the first terminal with which first contact 11 comes into contact and the second terminal with which second contact 12 comes into contact may be the same. For example, in the embodiment, first contact 11 and second contact 12 may be configured to come into contact with first module terminal M11 for power supply input and output.

It should be understood that the embodiment disclosed herein is illustrative and non-restrictive in every respect. The scope of the present invention is specified not by the description provided above, but by the appended claims, and is intended to include all modifications within the scope of the appended claims or the equivalents thereof.

### REFERENCE SIGNS LIST

1 Inspection apparatus
10A to 10D Contact unit
11 First contact
12 Second contact
111, 121 Module contact portion
112, 122 Surface mounting portion
113, 123 Spring portion
20 Pressing block
21 Flat portion
22 Rib
M1 Electronic component
M10 Module terminal
M11 First module terminal
M12 Second module terminal

1. An inspection apparatus that measures and inspects electrical characteristics of an electronic component including a plurality of terminals, the inspection apparatus comprising:
a first contact that comes into contact with a first terminal of the electronic component and through which a first current is passed during measurement; and
a second contact that comes into contact with a second terminal of the electronic component and through which a second current lower than the first current is passed during measurement, wherein
the first contact includes a first coating layer on a surface of a contact with the first terminal,
the second contact includes a second coating layer on a surface of a contact with the second terminal, and
the first coating layer and the second coating layer are different coating layers.

2. The inspection apparatus according to claim 1, wherein
the first coating layer has a lower electrical resistivity than the second coating layer.

3. The inspection apparatus according to claim 1, wherein
the second coating layer is less prone to metal oxide adhesion than the first coating layer.

4. The inspection apparatus according to claim 1, wherein
the first coating layer is a plating layer containing Ag, and
the second coating layer is a conductive carbon coating layer.

5. The inspection apparatus according to claim 1, wherein
the first contact and the second contact are produced using substrates identical to each other, the substrates being obtained by processing a plate material, and are disposed such that a plate thickness direction matches a pitch direction.

6. The inspection apparatus according to claim 5, further comprising a restricting portion that restricts a position of the second contact in the pitch direction.

7. The inspection apparatus according to claim 6, wherein
the first contact and the second contact each include a spring portion elastically deformable in a pressing direction when mounting the electronic component, and
the restricting portion is disposed on one or both sides of the spring portion of the second contact in the pitch direction.

8. The inspection apparatus according to claim 7, further comprising a pressing block that presses the first contact and the second contact in the pressing direction, wherein
the pressing block includes: a flat portion that comes into contact with the first contact and the second contact; and a rib that is formed to protrude from the flat portion and functions as the restricting portion.

9. The inspection apparatus according to claim 8, wherein
a height position of the flat portion that comes into contact with the first contact and a height position of the flat portion that comes into contact with the second contact are different from each other.
